(19) United States
(12) Patent Application Publication
(10) Pub. No.: US 2026/0005194 A1
(43) Pub. Date: Jan. 1, 2026

(54) SEMICONDUCTOR PACKAGES WITH A BRIDGE SEMICONDUCTOR DIE AND METHODS FOR FORMING THE SAME

(71) Applicant: STATS ChipPAC Pte. Ltd., Singapore (SG)

(72) Inventors: KyuWon LEE, Kyunggi-do (KR); JiSang LEE, Seoul (KR); KyungEun KIM, Incheon (KR); YoungDeuk LEE, Incheon (KR)

(21) Appl. No.: 19/253,947

(22) Filed: Jun. 29, 2025

(30) Foreign Application Priority Data
Jun. 28, 2024 (CN) 202410858460.1

(51) Int. Cl. H01L 23/00; H01L 23/13; H01L 25/065

(52) U.S. Cl. CPC H01L 24/83; H01L 23/13; H01L 24/14; H01L 24/16; H01L 24/26; H01L 24/32; H01L 24/33; H01L 24/73; H01L 24/81; H01L 24/92; H01L 25/0652; H01L 2224/1403; H01L 2224/14132; H01L 2224/16145; H01L 2224/16227; H01L 2224/26145; H01L 2224/32145; H01L 2224/32225; H01L 2224/33051; H01L 2224/33177; H01L 2224/73204; H01L 2224/81191; H01L 2224/81986; H01L 2224/83002; H01L 2224/83007; H01L 2224/83104; H01L 2224/83855; H01L 2224/83986; H01L 2224/92225

(57) ABSTRACT

A semiconductor package comprises: a package substrate having a first region, a second region and an opening between the first and second regions; a first semiconductor die mounted on the first region via a first set of solder bumps and having a first overhanging portion above the opening; a second semiconductor die mounted on the second region via a second set of solder bumps and having a second overhanging portion above the opening; a bridge semiconductor die mounted onto respective back surfaces of the first overhanging portion and the second overhanding portion via a third set of solder bumps, wherein the bridge semiconductor die is aligned with the opening; and an underfill layer filled between both of the first and second semiconductor dice and both of the package substrate and the bridge semiconductor die.

### TECHNICAL FIELD

The present application generally relates to semiconductor technology, and more particularly, to semiconductor packages with a bridge semiconductor die and methods for forming such semiconductor packages.

### BACKGROUND OF THE INVENTION

The semiconductor industry is constantly faced with complex integration challenges as consumers want their electronics to be smaller, faster and higher performance with more and more functionalities packed into a single device. For example, 2.5D semiconductor packages have been proposed with higher integration level. A kind of the 2.5D semiconductor packages may use an embedded semiconductor die or interposer to interconnect two other semiconductor dice together, all of which are placed on a same side of a package substrate.

However, it is noted that non-wetting issue may occur for the solder bumps of some 2.5D semiconductor packages, which lowers a yield of such packages.

Therefore, a need exists for further improvement of existing 2.5D semiconductor packages.

### SUMMARY OF THE INVENTION

An objective of the present application is to provide a semiconductor package with reduced non-wetting issue for solder bumps of the semiconductor package.

According to an aspect of the present application, there is provided a semiconductor package. The semiconductor package comprises: a package substrate having a first region, a second region and an opening between the first and second regions; a first semiconductor die mounted on the first region via a first set of solder bumps and having a first overhanging portion above the opening; a second semiconductor die mounted on the second region via a second set of solder bumps and having a second overhanging portion above the opening; a bridge semiconductor die mounted onto respective back surfaces of the first overhanging portion and the second overhanding portion via a third set of solder bumps, wherein the bridge semiconductor die is aligned with the opening; and an underfill layer filled between both of the first and second semiconductor dice and both of the package substrate and the bridge semiconductor die.

According to another aspect of the present application, a method for forming a semiconductor package is provided. The method comprises: providing a package substrate, wherein the package substrate has a first region, a second region and an opening between the first and second regions; providing a first semiconductor die and a second semiconductor die; forming a sacrificial film on respective back surfaces of a portion of the first semiconductor die and a portion of the second semiconductor die; aligning the portions of the first and second semiconductor dice formed with the sacrificial film with the opening of the package substrate such that the portions of the first and second semiconductor dice overhang above the opening; mounting the first semiconductor die on the first region via a first set of solder bumps and the second semiconductor die on the second region via a second set of solder bumps; forming a first underfill material between both of the first and second semiconductor dice and the package substrate; removing the sacrificial film from the first and second semiconductor dice; mounting a bridge semiconductor die onto the respective back surfaces of the overhanging portions of the first and second semiconductor dice via a third set of solder bumps; and forming a second underfill material between both of the overhanging portions of the first and second semiconductor dice and the bridge semiconductor die.

According to a further aspect of the present application, a method for forming a semiconductor package is provided. The method comprises: providing a package substrate, wherein the package substrate has a first region, a second region and an opening between the first and second regions; attaching a sacrificial film to the package substrate across the opening; mounting a first semiconductor die on the first region via a first set of solder bumps and a second semiconductor die on the second region via a second set of solder bumps, such that the first semiconductor die has a first overhanging portion above the opening with its back surface being in contact with the sacrificial film, and the second semiconductor die has a second overhanging portion above the opening with its back surface in contact with the sacrificial film; forming a first underfill material between both of the first and second semiconductor dice and the package substrate; removing the sacrificial film from the first and second semiconductor dice; mounting a bridge semiconductor die onto the respective back surfaces of the overhanging portions of the first and second semiconductor dice via a third set of solder bumps; and forming a second underfill material between both of the overhanging portions of the first and second semiconductor dice and the bridge semiconductor die.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 illustrates a semiconductor package 100 according to an embodiment of the present application.

FIGS. 2A to 2F illustrate a method for forming a semiconductor package according to an embodiment of the present application.

FIGS. 3A to 3F illustrate a method for forming a semiconductor package according to another embodiment of the present application.

FIGS. 4A to 4D illustrate a method for forming a semiconductor package according to a further embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, 2.5D semiconductor packages may use an embedded semiconductor die to interconnect two other semiconductor dice together, which may have non-wetting issue for solder bumps of such semiconductor packages. In particular, the embedded die or bridge semiconductor die may be flipped over and placed on a cavity substrate to interconnect two semiconductor dice which are both mounted on the same cavity substrate. It is noted by the inventors of the present application that the bridge semiconductor die may have smaller solder bumps than those solder bumps for mounting the two semiconductor dice which are also placed on the cavity substrate. The difference in bump size may increase difficulty in aligning top surfaces of the sets of solder bumps on the cavity substrate, as these solder bumps may have different heights with respect to a front surface of the cavity substrate, resulting in the non-wetting issue.

In order to resolve the above issue, a semiconductor package which mounts or attaches a bridge semiconductor die onto two primary semiconductor dice rather than a package substrate are proposed. As the bridge semiconductor die is directly attached onto the primary semiconductor dice via a set of solder bumps, it is not needed to align vertically the set of solder bumps and other solder bumps inside the semiconductor package, non-wetting issue which may occur to existing 2.5D semiconductor packages can be addressed.

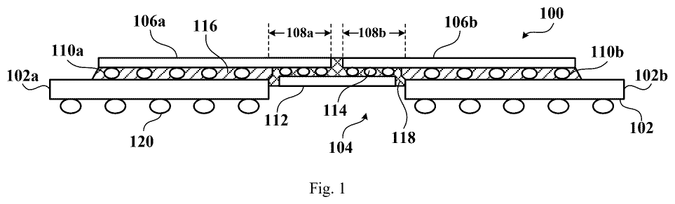

FIG. 1 illustrates a semiconductor package 100 according to an embodiment of the present application.

As shown in FIG. 1, the semiconductor package 100 includes a package substrate 102 where various components and other structures are mounted and formed. The package substrate 102 includes a front side facing upward in the direction shown in FIG. 1, and a back side opposite to the front side. In some embodiments, the package substrate 102 may be made of silicon or other semiconductor materials, or may include a printed circuit board (PCB), a carrier substrate, a ceramic substrate, a laminate interposer, a strip interposer, a leadframe, or other suitable substrates. In some examples, the package substrate 102 may include redistribution layers or structures having one or more dielectric layers and one or more conductive layers between and through dielectric layers. Thus, the various components and other structure on either one side or both sides of the package substrate 102 may be electrically coupled with each other to form an integrated electronic system. In the embodiment shown in FIG. 1, most of the electronic components are mounted on the front side of the package substrate 102, only solder bumps 120 are mounted on the back side of the package substrate 102. As such, the electronic components mounted on the front side of the package substrate 102 can be electrically coupled to the solder bumps 120 through the package substrate 102, and be further electrically coupled to an external system such as a power system or a controller when the semiconductor package 100 is connected with such external system.

In particular, the package substrate 102 has a first region 102a and a second region 102b, which are used for mounting of respective semiconductor dice 106a and 106b, as will be elaborated below. Furthermore, an opening 104 is formed between the first and second regions 102a and 102b. It can be appreciated that FIG. 1 is a cross sectional view of the semiconductor package 100, and thus, the package 102 can be formed as a single piece, i.e., the first region 102a and the second region 102b can be connected with each other at a position or positions where the opening 104 does not extend. That is, the package substrate 102 may be shaped as a donut, with the opening 104 at its center. The opening 104 may extend through the package substrate 102 so as to allow a bridge semiconductor die 112 to pass therethrough. In other words, the opening 104 has a bigger size than the bridge semiconductor die 112. In some embodiments, the opening 104 may have a same or similar shape as the bridge semiconductor die 112, and have a diameter or size that is at least 110%, or preferably at least 120%, or more preferably at least 130% times of that of the bridge semiconductor die 112. It can be appreciated that the opening 104 should not be too large as a too large opening 104 may leave a relatively smaller space on the package substrate 102 for mounting other components.

The first semiconductor die 106a is mounted on the first region 102a via a first set of solder bumps 110a. A portion of the first semiconductor die 106a is right above on the first region 102a, while another portion 108a of the first semiconductor die 106a may overhang above the opening 104, i.e., extending from the first region 102a to the opening 104. Similarly, the second semiconductor die 108a is mounted on the second region 102b via a second set of solder bumps 110b. A portion of the second semiconductor die 106b is right above on the second region 102b, while another portion 108b of the second semiconductor die 106b may overhang above the opening 104, i.e., extending from the second region 102b to the opening 104. In some embodiments, the first overhanging portion 108a has a length smaller than a half of that of the first semiconductor die 106a, and the second overhanging portion 108b has a length smaller than a half of that of the second semiconductor die 106b. As such, respective mass centers of the first and second semiconductor dices 106a and 106b can be right above the first or second region 102a or 102b and thus can be stably supported on the package substrate 102. The overhanging portion 108a and 108b provide a platform where the bridge semiconductor die 112 may be attached.

In some embodiments, the first semiconductor die 106a and the second semiconductor die 106b may have the same thickness, but in some alternative embodiments, these two semiconductor dice 106a and 106b may have different thicknesses. However, as both of the two semiconductor dice 106a and 106b are mounted on the package substrate 102 via respective sets of solder bumps 110a and 110b, the sets of solder bumps 110a and 110b should have substantially the same height such that back surfaces (i.e., lower surfaces in the direction of FIG. 1) of the overhanging portions 108a and 108b may be substantially aligned with each other vertically with respect to the package substrate 102. As such, the overhanging portions 108a and 108b provide a flat platform where the bridge semiconductor die 112 can be mounted.

In particular, the bridge semiconductor die 112 is mounted onto the back surfaces of the overhanging portions 108a and 108b via a third set of solder bump 114. As mentioned above, the bridge semiconductor die 112 may be aligned with the opening 104 in a vertical direction such that it can pass through the opening 104 and be mounted onto the overhanging portions 108a and 108b. In some embodiments, the bridge semiconductor die 112 may have a smaller size than the first and second semiconductor dice 106a and 106b on the package substrate 102, and accordingly the third set of solder bumps 114 may similarly have a smaller size than that of the first and second sets of solder bumps 110a and 110b to allow for a smaller pitch of solder bumps on the bridge semiconductor die 112. Furthermore, since the bridge semiconductor die 112 is mounted on the semiconductor dice 106a and 106b and is not disposed on the package substrate 102, the difference in size between the solder bumps 114 and the solder bumps 110a and 110b may not affect the mounting of the bridge semiconductor die 112. In other words, the bridge semiconductor die 112 can be mounted onto the semiconductor dice 106a and 106b using any suitable sized solder bumps, without incurring any non-wetting issue. In this way, a yield of such semiconductor packages in mass production can be improved.

Furthermore, an underfill layer is filled between both of the first and second semiconductor dice 106a and 106b and both of the package substrate 102 and the bridge semiconductor die 112. In some embodiments, the underfill layer may have two portions, i.e., a first underfill portion 116 between the first and second semiconductor dice 106a and 106b and the package substrate 102, and a second underfill portion 118 between the first and second overhanging portions 108a and 108b and the bridge semiconductor die 112. It can be appreciated that there may be some small gap between the bridge semiconductor die 112 and the package substrate 102 in the opening 104, and thus in some embodiments the second underfill portion 118 may extend a bit to fill the gap and then be connected to the first underfill portion 116. In this way, the underfill layer may be an integral layer. In some embodiments, the two underfill portions may be formed of the same material or of different materials. For example, the underfill layer may be made of a polymer composite material, such as epoxy resin with filler, epoxy acrylate with filler, or polymer with proper filler, but the scope of this application is not limited thereto. Preferably, the two underfill portions 116 and 118 may be formed separately in two processes. It can be appreciated that the first underfill portion 116 may be filled between the first and second semiconductor dice 106a and 106b and the package substrate 102 to enclose generally the two sets of solder bumps 110a and 110b, and thus it should have a height generally equal to that of the solder bumps 110a and 110b. Furthermore, the second underfill portion 118 is filled between the first and second overhanging portions 108a and 108b and the bridge semiconductor die 112, and should have a height equal to that of the solder bumps 114. In some embodiments where the solder bumps 110a and 110b are bigger than the solder bumps 114, the first underfill portion 116 may have a height greater than that of the second underfill portion 118. In some embodiments, depending on the height of the solder bumps 114, the thickness of the bridge semiconductor die 112 and the height of the solder bumps 110a and 110b, a lower surface of the bridge semiconductor die 112 may be lower than an upper surface of the package substrate 102 but higher than a lower surface of the package substrate 102, i.e., a portion of the bridge semiconductor die 112 is accommodated within the opening 104. In this way, the second under fill portion 118 can connect the various components, including the first and second semiconductor dice 106a and 106b, the first under fill portion 116, the bridge semiconductor die 112 and the package substrate 102 together. However, it can be appreciated that in some other embodiments, an entirety of the bridge semiconductor die 112 can be not accommodated within the opening 104.

As can be seen from FIG. 1, the bridge semiconductor die 112 is seated within the cavity formed by the package substrate 102 at the opening 104 and the overhanging portions 108a and 108b, and is further secured therein by the underfill layer and the solder bumps 114. In this way, the bridge semiconductor die 112 can physically connect the two semiconductor dice 106a and 106b together. Also, the solder bumps 114 may be aligned with both conductive patterns or pads of the bridge semiconductor 112 and conductive patterns or pads of the first overhanging portion 108a or the second overhanging portion 108b, such that the first and second semiconductor dice 106a and 106b can be electrically connected with each other as well.

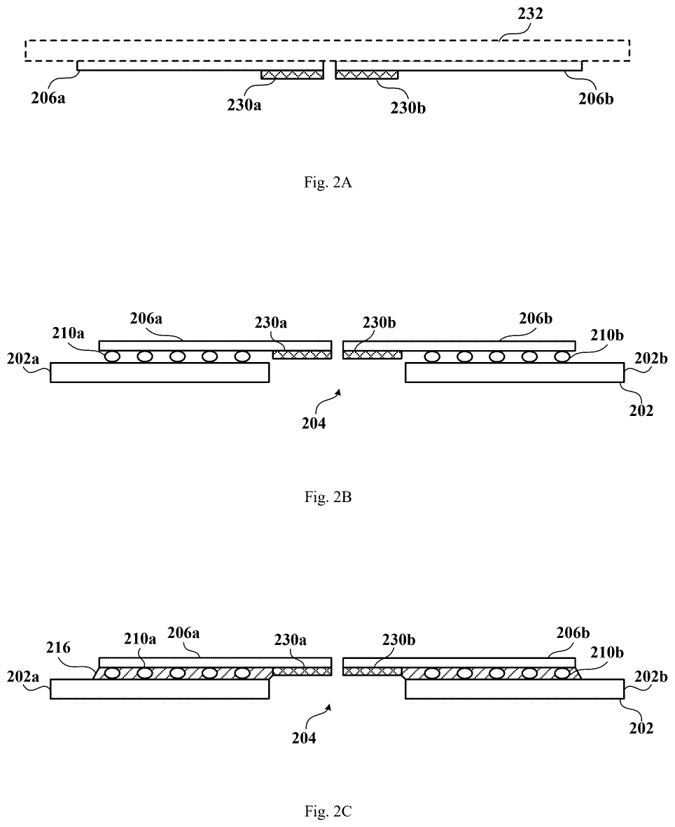

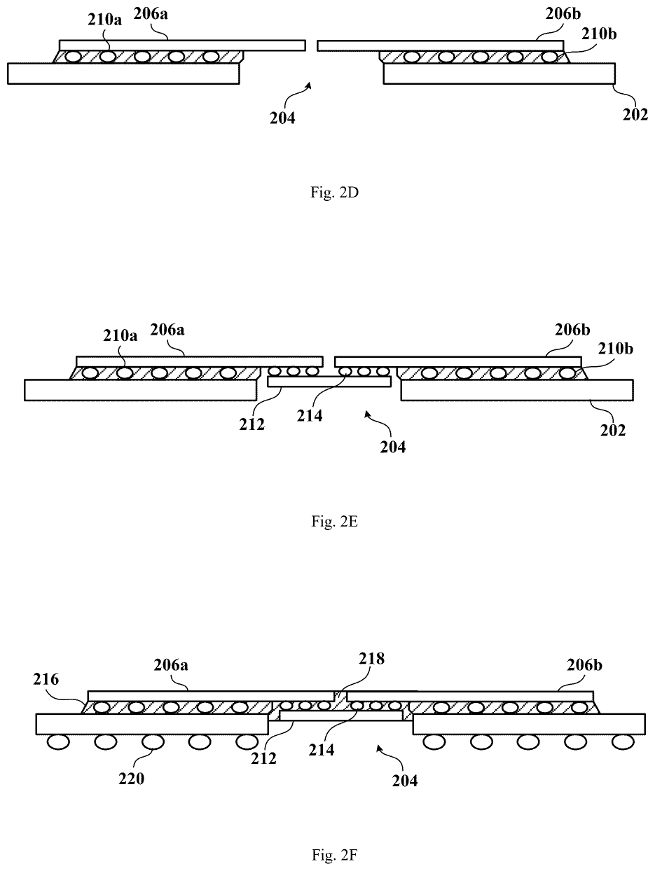

FIGS. 2A to 2F illustrate a method for forming a semiconductor package according to an embodiment of the present application. For example, the method can be used to form the semiconductor package 100 shown in FIG. 1.

As shown in FIG. 2A, a first semiconductor die 206a and a second semiconductor die 206b are provided. In some embodiments, the semiconductor dice 206a and 206b may be attached onto a carrier 232, for example, using adhesive, or vacuum or electrostatic attraction. The common carrier 232 can ensure that upper surfaces of the semiconductor dice 206a and 206b can be aligned with each other vertically. Furthermore, a sacrificial film 230a can be formed on a back surface (i.e., a lower surface in the direction of FIG. 2A) of a portion of the first semiconductor die 206a, and another sacrificial film 230b can be formed on a back surface of a portion of the second semiconductor die 206b. In some embodiments, the sacrificial films 230a and 230b can be formed in a single process, for example, using a film deposition process (e.g., spin coating, spraying, etc.) and a subsequent patterning process (e.g., lithography), and can thus be formed of a same material such as a photoresist material. In some other embodiments, the sacrificial films 230a and 230b can be tapes or similar materials that can be attached onto the semiconductor dice 206a and 206b via adhesive. It can be appreciated that the sacrificial films 230a and 230b are used to temporarily occupy a space for a bridge semiconductor die to be attached, and thus they may be attached onto respective peripheral regions of the semiconductor dice 206a and 206b which are adjacent to each other. Also, although it is shown in FIG. 2A the sacrificial films 230a and 230b are separated from each other, in some alternative embodiments, the sacrificial films 230a and 230b can be formed together as a single piece.

Next, as shown in FIG. 2B, a package substrate 202 is provided. The package substrate 202 has a first region 202a, a second region 202b and an opening 204 between the first and second regions 202a and 202b. A central portion of the combination of the first and second semiconductor dice 206a and 206b can be aligned with the opening 204 of the package substrate 202. In particular, the first semiconductor die 206a may be placed generally above the first region 202a, and the second semiconductor die 206b may be placed generally above the second region 202b. As such, the portions of the first and second semiconductor dice 206a and 206b attached with the sacrificial films 230a and 230b may overhang above the opening 204, and the sacrificial films 230a and 230b may overlap with and face toward the opening 204. Next, the first semiconductor die 206a is mounted on the first region 202a via a first set of solder bumps 210a, and the second semiconductor die 206b is mounted on the second region 202b via a second set of solder bumps 210b. In some embodiments, the first set of solder bumps 210a may have a height equal to that of the second set of solder bumps 210b.

Next, as shown in FIG. 2C, a first underfill material 216 is formed between both of the first and second semiconductor dice 206a and 206b and the package substrate 202. The first underfill material 216 may secure the attachment of the first and second semiconductor dice 206a and 206b on the package substrate 202 via the solder bumps 210a and 210b. Due to the existence of the sacrificial films 230a and 230b on the respective back surfaces of the first and second semiconductor dice 206a and 206b, the first underfill material 216 may not extend beyond respective edges of the sacrificial films 230a and 230b further into the opening 204 of the package substrate 204.

Next, as shown in FIG. 2D, the first underfill material 216 may be cured and solidify, and then the sacrificial film can be removed from the first and second semiconductor dice 206a and 206b, to expose the back surfaces of their respective portions overhanging above the opening 204. In some embodiments, the sacrificial films may be patterned photoresists which may be removed, for example, using a wet etching process or a dry etching process. In some other embodiments, the sacrificial films can be removed using stripping or similar mechanical separation processing.

Next, as shown in FIG. 2E, a bridge semiconductor die 212 is mounted onto the respective back surfaces of the overhanging portions of the first and second semiconductor dice 206a and 206b via a set of solder bumps 214. In particular, the bridge semiconductor die 212 may have a size smaller than that of the opening 204, and can pass through the opening 204 from a position under the package substrate 202 onto the overhanging portions of the first and second semiconductor dice 206a and 206b. In some embodiments, the solder bumps 214 may have a height smaller than that of the sets of solder bumps 210a and 210b, and thus an upper surface of the bridge semiconductor die 212 can be higher than the front surface of the package substrate 202. Moreover, as the bridge semiconductor die 212 can be mounted directly using the solder bumps 214 without the need to align the solder bumps 214 with the other sets of solder bumps 210a and 210b, non-wetting issue for existing semiconductor packages with a bridge semiconductor die for connection can be avoided. In some embodiments, at least a portion of the bridge semiconductor die 212 is accommodated within the opening 204.

Next, as shown in FIG. 2F, a second underfill material 218 is formed between both of the overhanging portions of the first and second semiconductor dice 206a and 206b and the bridge semiconductor die 212. The second underfill material 218 can be connected with the first underfill material 216 and surround the solder bumps 214 to secure the attachment of the bridge semiconductor die 212 on the first and second semiconductor dice 206a and 206b. In some embodiments, the first underfill material 216 has a thickness greater than that of the second underfill material 218. Similarly, the second underfill material 218 can be cured and thus solidify. Afterwards, solder bumps 220 can be formed on a back side of the package substrate 202. In this way, a semiconductor package can be formed.

As aforementioned, a carrier may be used to align the upper surfaces of the first and second semiconductor dice. In some embodiments, after mounting the first semiconductor die on the first region via a first set of solder bumps and the second semiconductor die on the second region via a second set of solder bumps, i.e., after the step shown in FIG. 2B, or after the step shown in FIG. 2C or even later, the carrier can be removed from the first and second semiconductor dice.

It can be appreciated that the alignment of the upper surfaces of the first and second semiconductor dice may be performed in other proper manners. For example, in the step shown in FIG. 2A, the two semiconductor dice 206a and 206b may be formed with the sacrificial films 230a and 230b separately, and thus they may not be placed on or attached to the carrier 232 for alignment. Instead, after the step shown in FIG. 2D where the underfill material 216 is filled between the package substrate 202 and the semiconductor dice 206a and 206b, a carrier or chase (not shown) may be applied to the semiconductor dices 206a and 206b to press them against the package substrate 202. In this way, the upper surfaces of the semiconductor dices 206a and 206b can be aligned with each other, and accordingly the lower surfaces of the semiconductor dices 206a and 206b can be aligned with each other to provide an even and flat surface for the mounting of the bridge semiconductor die in subsequent steps.

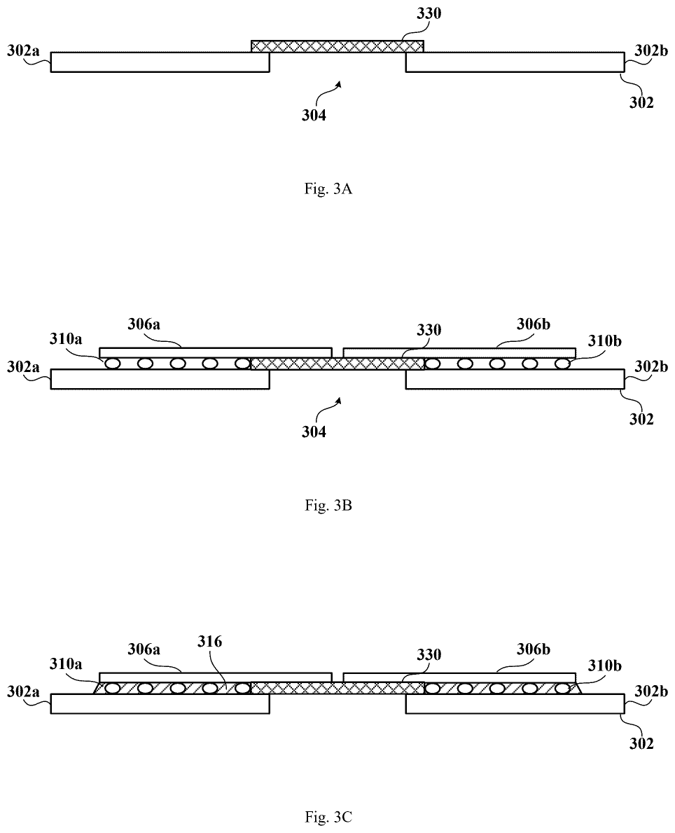

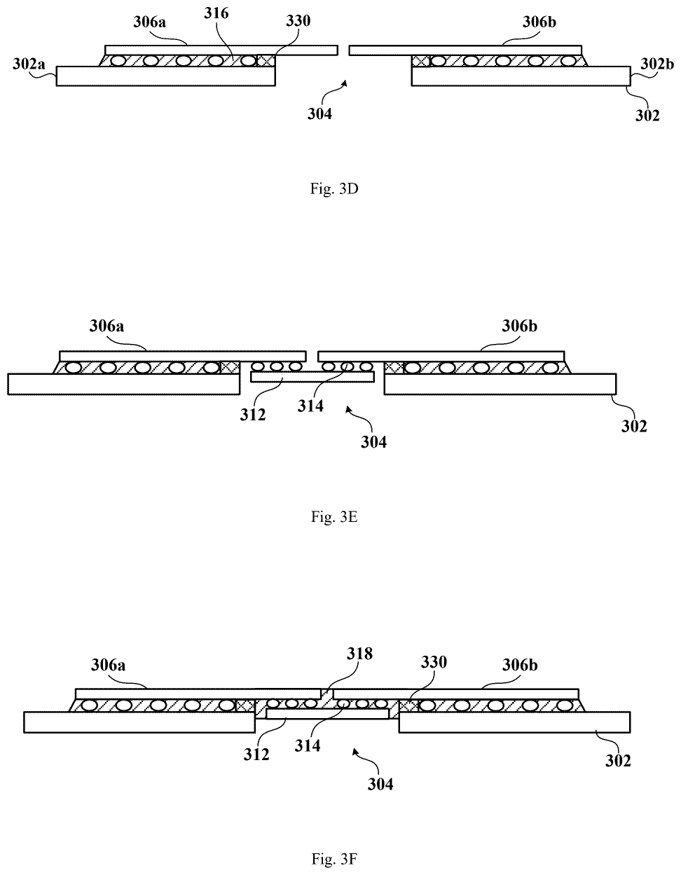

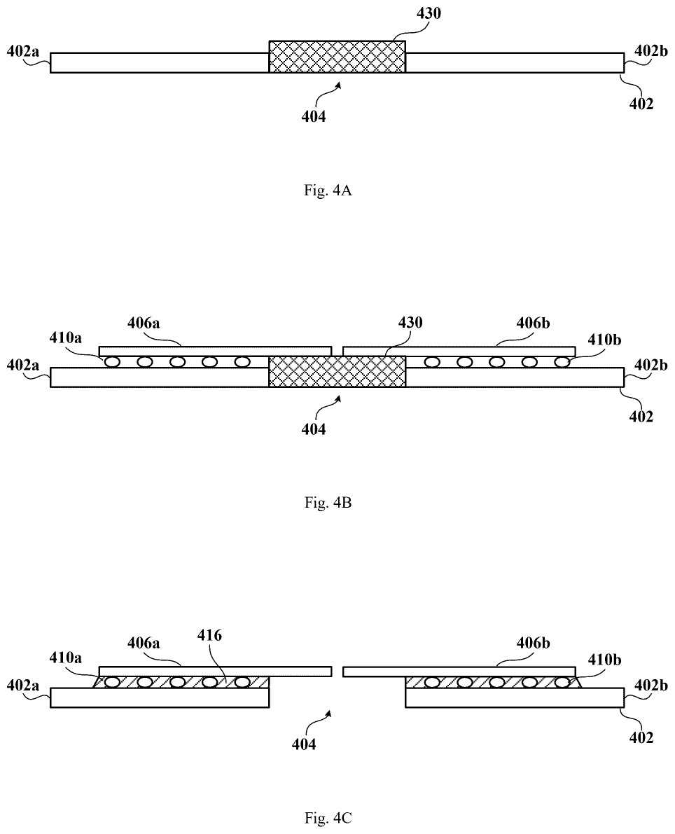

FIGS. 3A to 3F illustrate a method for forming a semiconductor package according to another embodiment of the present application. Different from the method shown in FIGS. 2A to 2F, a sacrificial film for occupying a space for a bridge semiconductor die is formed on the package substrate instead of on the semiconductor dices, which will be elaborated below in more details.

As shown in FIG. 3A, a package substrate 302 is provided. The package substrate 302 has a first region 302a, a second region 302b and an opening 304 between the first and second regions 302a and 302b. Furthermore, a sacrificial film 330 is attached to the package substrate 302 across the opening 304. In particular, the sacrificial film 330 may be attached on the front surface of the package substrate 302, such that the sacrificial film 330 can extend from the first region 302a to the second region 302b. It can be appreciated that the sacrificial film 330 should have a strength that can maintain it suspending across the opening 304 as there is no support in the opening 304. In some embodiments, the sacrificial film 330 may be a tape, which may be attached on the package substrate 302 via adhesive. In some preferred embodiments, the sacrificial film 330 may have a size greater than the opening 304 such that the opening 304 can be fully covered by the sacrificial film 330.

Next, as shown in FIG. 3B, a first semiconductor die 306a is mounted on the first region 302a via a first set of solder bumps 310a, and a second semiconductor die 306b is mounted on the second region 302b via a second set of solder bumps 310b. The solder bumps 302a and 302b may have the same height as the sacrificial film 330, such that respective back surfaces of the first semiconductor die 306a and the second semiconductor die 306b can be in contact with an upper surface of the sacrificial film 330. In other words, the heights or size of the solder bumps 310a and 310 depends on the thickness of the sacrificial film 330. Furthermore, since the sacrificial film 330 suspends over the opening 304, the first semiconductor die 306a may have a first overhanging portion above the opening 304 with its back surface being in contact with the sacrificial film 330, and the second semiconductor die 306b also has a second overhanging portion above the opening 304 with its back surface being in contact with the sacrificial film 330.

Next, as shown in FIG. 3C, a first underfill material 316 is formed between both of the first and second semiconductor dice 306a and 306b and the package substrate 302. Due to the existence of the sacrificial film 330, the first underfill material 316 may not be formed on portions of the first and second regions 302a and 302b that are close to the opening 304. But the first underfill material 316 can enclose the solder bumps 310a and 310b to secure them between the semiconductor dice 306a and 306b and the package substrate 302.

Next, as shown in FIG. 3D, the sacrificial film is removed from the first and second semiconductor dice 306a and 306b. For example, the sacrificial film can be removed using an etching process, mechanical detach, UV irradiation, or laser ablation. In particular, as a peripheral portion of the sacrificial film 330 is filled between the semiconductor dice 306 and 306b and the package substrate 302, such peripheral portion may not be moved by the etching process and thus remain there, as is shown in FIG. 3D. The removal of the sacrificial film may expose back surfaces of the portions of the semiconductor dice 306a and 306b which overhang above the opening 304. It can be appreciated that in some examples, further processing such as wet or dry etch which is generally isotropic can be performed to remove the remaining portion of the sacrificial film between the semiconductor dice 306 and 306b and the package substrate 302, as long as the processing is a selective processing directed to the material of the sacrificial film.

Next, as shown in FIG. 3E, a bridge semiconductor die 312 is mounted onto the respective back surfaces of the overhanging portions of the first and second semiconductor dice 306a and 306b via a set of solder bumps 314. In some embodiments, the solder bumps 314 may have a height smaller than that of the sets of solder bumps 310a and 310b, and thus an upper surface of the bridge semiconductor die 312 can be higher than the front surface of the package substrate 302. In some embodiments, at least a portion of the bridge semiconductor die 312 is accommodated within the opening 304.

Next, as shown in FIG. 3F, a second underfill material 318 is formed between both of the overhanging portions of the first and second semiconductor dice 306a and 306b and the bridge semiconductor die 312. The second underfill material 318 can be connected with the first underfill material 316 via the remaining portion of the sacrificial film 330, and can enclose the solder bumps 314 to secure the attachment of the bridge semiconductor die 312 on the first and second semiconductor dice 306a and 306b. In some embodiments, the first underfill material 316 has a thickness greater than that of the second underfill material 318. Afterwards, solder bumps 320 can be formed on a back side of the package substrate 302. In this way, a semiconductor package can be formed.

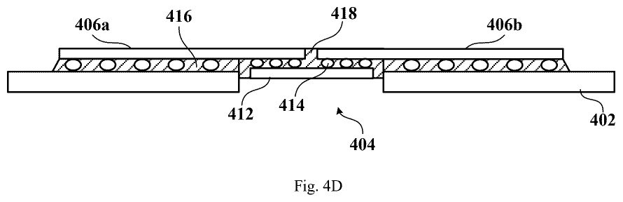

FIGS. 4A to 4D illustrate a method for forming a semiconductor package according to a further embodiment of the present application. Most steps of the method are similar as those in the method shown in FIGS. 3A to 3F, except some earlier steps as will be elaborated below.

As shown in FIG. 4A, a package substrate 402 is provided. The package substrate 402 has a first region 402a, a second region 402b and an opening 404 between the first and second regions 402 and 404. Furthermore, a sacrificial film 430 is attached to the package substrate 402 across the opening 404. In particular, the sacrificial film 430 may be fitted within and across the opening 404. For example, the sacrificial film 430 may have a shape and size substantially the same as or slightly greater than that of the opening 404. As such, the sacrificial film 430 may not be displaced in some subsequent steps. The sacrificial film 430 may protrude from a front surface (an upper surface in the direction shown in FIG. 4A) of the package substrate 402, and the protruding portion of the sacrificial film 430 may later serve for supporting two semiconductor dices to be mounted. Preferably, the sacrificial film 430 may have a thickness greater than that of the package substrate 402.

Next, as shown in FIG. 4B, a first semiconductor die 406a is mounted on the first region 402a via a first set of solder bumps 410a, and a second semiconductor die 406b is mounted on the second region 402b via a second set of solder bumps 410b. The solder bumps 402a and 402b may have the same height as the protruding portion of the sacrificial film 430, such that respective back surfaces of the first semiconductor die 406a and the second semiconductor die 406b can be in contact with an upper surface of the sacrificial film 430.

Next, as shown in FIG. 4C, a first underfill material 416 is formed between both of the first and second semiconductor dice 406a and 406b and the package substrate 402. Due to the existence of the sacrificial film, the first underfill material 416 may extend from the first and second regions 402a and 402b till the opening 404. Afterwards, the sacrificial film is removed from the first and second semiconductor dice 406a and 406b. Different from the embodiment shown in FIGS. 3A to 3F, as the sacrificial film is generally fitted within the opening 404 and not filled between the package substrate 402 and the semiconductor dice 406a and 406b, the sacrificial film can be generally fully removed.

Next, as shown in FIG. 4D, a bridge semiconductor die 412 is mounted onto the respective back surfaces of overhanging portions of the first and second semiconductor dice 406a and 406b via a set of solder bumps 414. Afterwards, a second underfill material 418 is formed between both of the overhanging portions of the first and second semiconductor dice 406a and 406b and the bridge semiconductor die 412. The second underfill material 418 can be connected with the first underfill material 416 at a boundary of the opening 404. In this way, a semiconductor package can be formed.

The discussion herein includes numerous illustrative figures that show various portions of a semiconductor package and a method for forming the semiconductor package. For illustrative clarity, such figures do not show all aspects of each exemplary method. Any of the example methods provided herein may share any or all characteristics with any or all other methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A semiconductor package, comprising:
a package substrate having a first region, a second region and an opening between the first and second regions;
a first semiconductor die mounted on the first region via a first set of solder bumps and having a first overhanging portion above the opening;
a second semiconductor die mounted on the second region via a second set of solder bumps and having a second overhanging portion above the opening;
a bridge semiconductor die mounted onto respective back surfaces of the first overhanging portion and the second overhanding portion via a third set of solder bumps, wherein the bridge semiconductor die is aligned with the opening; and
an underfill layer filled between both of the first and second semiconductor dice and both of the package substrate and the bridge semiconductor die.

2. The semiconductor package of claim 1, wherein the first set of solder bumps have a height equal to that of the second set of solder bumps.

3. The semiconductor package of claim 2, wherein the third set of solder bumps have a height smaller than that of the first and second sets of solder bumps.

4. The semiconductor package of claim 1, wherein the underfill layer comprises a first underfill portion between the first and second semiconductor dice and the package substrate, and a second underfill portion between the first and second overhanging portions of the first and second semiconductor dice and the bridge semiconductor die.

5. The semiconductor package of claim 4, wherein the first underfill portion has a thickness greater than that of the second underfill portion.

6. The semiconductor package of claim 4, wherein the first underfill portion and the second underfill portion are formed separately.

7. The semiconductor package of claim 1, wherein at least a portion of the bridge semiconductor die is accommodated within the opening.

8. The semiconductor package of claim 1, wherein the first overhanging portion has a length smaller than a half of that of the first semiconductor die, and the second overhanging portion has a length smaller than a half of that of the second semiconductor die,

9. A method for forming a semiconductor package, wherein the method comprises:
providing a package substrate, wherein the package substrate has a first region, a second region and an opening between the first and second regions;
providing a first semiconductor die and a second semiconductor die;
forming a sacrificial film on respective back surfaces of a portion of the first semiconductor die and a portion of the second semiconductor die;
aligning the portions of the first and second semiconductor dice formed with the sacrificial film with the opening of the package substrate such that the portions of the first and second semiconductor dice overhang above the opening;
mounting the first semiconductor die on the first region via a first set of solder bumps and the second semiconductor die on the second region via a second set of solder bumps;
forming a first underfill material between both of the first and second semiconductor dice and the package substrate;
removing the sacrificial film from the first and second semiconductor dice;
mounting a bridge semiconductor die onto the respective back surfaces of the overhanging portions of the first and second semiconductor dice via a third set of solder bumps; and
forming a second underfill material between both of the overhanging portions of the first and second semiconductor dice and the bridge semiconductor die.

10. The method of claim 9, wherein the first set of solder bumps have a height equal to that of the second set of solder bumps.

11. The method of claim 10, wherein the third set of solder bumps have a height smaller than that of the first and second sets of solder bumps.

12. The method of claim 9, wherein the first underfill material has a thickness greater than that of the second underfill material.

13. The method of claim 9, wherein at least a portion of the bridge semiconductor die is accommodated within the opening.

14. The method of claim 9, wherein the sacrificial film is formed using a film deposition process and a subsequent film patterning process.

15. The method of claim 9, wherein before forming a sacrificial film on respective back surfaces of a portion of the first semiconductor die and a portion of the second semiconductor die, the method further comprises: attaching the first and second semiconductor dice onto a carrier; and after mounting the first semiconductor die on the first region via a first set of solder bumps and the second semiconductor die on the second region via a second set of solder bumps, the method further comprises removing the carrier from the first and second semiconductor dice.

16. A method for forming a semiconductor package, wherein the method comprises:
providing a package substrate, wherein the package substrate has a first region, a second region and an opening between the first and second regions;
attaching a sacrificial film to the package substrate across the opening;
mounting a first semiconductor die on the first region via a first set of solder bumps and a second semiconductor die on the second region via a second set of solder bumps, such that the first semiconductor die has a first overhanging portion above the opening with its back surface being in contact with the sacrificial film, and the second semiconductor die has a second overhanging portion above the opening with its back surface in contact with the sacrificial film;
forming a first underfill material between both of the first and second semiconductor dice and the package substrate;
removing the sacrificial film from the first and second semiconductor dice;
mounting a bridge semiconductor die onto the respective back surfaces of the overhanging portions of the first and second semiconductor dice via a third set of solder bumps; and
forming a second underfill material between both of the overhanging portions of the first and second semiconductor dice and the bridge semiconductor die.

17. The method of claim 16, wherein the first underfill material has a thickness greater than that of the second underfill material.

18. The method of claim 16, wherein at least a portion of the bridge semiconductor die is accommodated within the opening.

19. The method of claim 16, wherein attaching a sacrificial film to the package substrate across the opening comprises:
attaching the sacrificial film on a front surface of the package substrate such that the sacrificial film extends from the first region to the second region across the opening.

20. The method of claim 16, wherein attaching a sacrificial film to the package substrate across the opening comprises:
fitting the sacrificial film within the opening such that the sacrificial film protrudes from a front surface of the package substrate.
